(19) United States
(12) Patent Application Publication
(10) Pub. No.: US 2010/0101939 A1
(43) Pub. Date: Apr. 29, 2010

(54) Method For Preparing Zinc Oxide Nano Rod Substrate

(75) Inventors: Kuo-Chuan Ho, Taipei (TW); Wen-Yen Chiu, Taipei (TW); Chi-An Dai, Taipei (TW); Chii-Wann Lin, Taipei (TW); Po-Yen Chen, Taipei (TW); Chia-Yu Lin, Taipei (TW); Wei- Yi Feng, Taipei (TW)

Correspondence Address: WPAT, PC;INTELLECTUAL PROPERTY ATTORNEYS, 7225 BEVERLY ST., ANNANDALE, VA, 22003, US

(73) Assignee: National Taiwan University, Taipei (TW)

(21) Appl. No.: 12/604,589

(22) Filed: Oct. 23, 2009

(30) Foreign Application Priority Data
Oct. 24, 2008 (TW) 097140791

(51) Int. Cl. C23C 14/34; C23C 14/58

(52) U.S. Cl. 204/192.15

(57) ABSTRACT

The present invention discloses a method for preparing a zinc oxide (ZnO) nano rod substrate. First, a layer of ZnO nano particles was sputtered on the substrate and the ZnO nano rods were grown with the hydrothermal reaction on this substrate. Repeatedly proceeding the hydrothermal reaction can obtain a higher aspect ratio of the ZnO nano rods. According to this method, highly orientated ZnO nano rods will be prepared. The ZnO nano rods possess very high surface area and provide very effective pH tuning ability. The growth of ZnO nano rods on the plastic and fiber substrate were also prepared to increase the applicability.

### BACKGROUND OF THE INVENTION

1. Field of the Invention

The present invention is generally related to a method for preparing a zinc oxide nano rod substrate, and more particularly to a method for preparing a regularly arranged zinc oxide nano rod substrate.

2. Description of the Prior Art

A nano material is a material having one dimension within a nanometer scale. Usually, it requires a material having only one dimension among three to be within a nanometer scale. According to the profile of a material, nano materials can be divided into a zero-dimensional material (such as nano particle, nano cluster), one-dimensional material (such as nano fiber, nano tube, nano rod), and two-dimensional material (such as nano membrane).

Among the above, a zinc oxide nano material has special optical and electrical properties. A zinc oxide nano material can absorb ultraviolet light and thus can be applied as an ultraviolet inhibitor and a fluorescent material. Besides, the special opto-electrical function of a zinc oxide nano material can be applied in an anti-static agent, opto-electrical material, and etc. In addition, a zinc oxide nano material can also be applied in various fields such as a catalyst, rubber curing, antiseptic, deodorant, and etc. Most importantly, a zinc oxide nano material has advantages of being non-toxic, having no skin stimulus effect, having self-cleaning and pH buffering properties and so forth so that more application fields can be found. Currently, the commonly-seen preparation methods include the chemical reduction method, the hydrothermal synthetic method, the sol-gel method, and etc.

Therefore, currently how to fix a zinc oxide nano material having a large reactive surface area on a textile to enhance the application convenience of the zinc oxide nano material is an important technical issue for the industry.

### SUMMARY OF THE INVENTION

In light of the above background, in order to fulfill the industrial requirements, the invention provides a method for preparing a zinc oxide nano rod substrate.

One characteristic of the present invention is to disclose a method utilizing the sputtering method and the hydrothermal reaction to prepare a zinc oxide nano rod substrate. The method comprises the following steps. At first, under room temperature, a blending process is performed to blend a zinc salt and an organic base reagent in an aqueous solution to form a mixture solution. Then, a substrate and a zinc oxide material are provided and a sputtering process is performed to have the zinc oxide material become nano particles and evenly deposited on the surface of the substrate to form an intermediate substrate. Finally, the intermediate substrate is immersed in the mixture solution and placed in a sealed container at a specific temperature so that a hydrothermal reaction is performed. Through the hydrothermal reaction, the zinc oxide nano particle as a nucleating center grows oriented to form a type of zinc oxide nano rods so as to form the zinc oxide nano rod substrate. After the sputtering process, an annealing process can be performed.

To sum up, the invention discloses a method for preparing a zinc oxide nano rod substrate. The method utilizes the sputtering method and the hydrothermal reaction to prepare a zinc oxide nano rod substrate. In addition to prepare a regularly arranged zinc oxide nano rod substrate, the merits of the method include controlling the size of the zinc oxide nano rod by repeatedly performing the hydrothermal reaction.

In addition, the zinc oxide nano rod substrate prepared by the method according to the present invention has a large surface area and high pH buffering efficiency. Besides, the surface of the zinc oxide nano rod substrate is hydrophobic so that the zinc oxide nano rod substrate posses a self-cleaning function. The air between the zinc oxide nano rods has a warm-up effect on cloth. Thus, the present invention does have the economic advantages for industrial applications.

### BRIEF DESCRIPTION OF THE DRAWINGS

FIG. 1 shows the relation between the different hydrothermal reaction time and the length and diameter of the zinc oxide nano rod for the zinc oxide nano rod substrate;

FIG. 2A shows a cross-sectional scanning electron microscope (SEM) image of the zinc oxide nano rod substrate prepared through the hydrothermal reaction for 6 hrs;

FIG. 2B shows a top view of the scanning electron microscope (SEM) image of the zinc oxide nano rod substrate prepared through the hydrothermal reaction for 6 hrs;

FIG. 3A shows a cross-sectional scanning electron microscope (SEM) image of the zinc oxide nano rod substrate prepared through performing the hydrothermal reaction twice;

FIG. 3B shows a top view of the scanning electron microscope (SEM) image of the zinc oxide nano rod substrate prepared through performing the hydrothermal reaction twice;

FIG. 4A shows a cross-sectional scanning electron microscope (SEM) image of the zinc oxide nano rod substrate prepared through performing the hydrothermal reaction four times;

FIG. 4B shows a top view of the scanning electron microscope (SEM) image of the zinc oxide nano rod substrate prepared through performing the hydrothermal reaction four times;

FIG. 5 shows the relation between the number of cycles and the length and diameter of the zinc oxide nano rod for the zinc oxide nano rod substrate;

FIG. 6 shows pH buffer testing graphs of the zinc oxide nano rod substrate;

FIG. 7 shows a scanning electron microscope (SEM) image of the non-woven cloth substrate after sputtering zinc oxide; and

FIG. 8 shows a scanning electron microscope (SEM) image illustrating the zinc oxide nano rods regularly arranged on the non-woven cloth.

### DESCRIPTION OF THE PREFERRED EMBODIMENTS

What is probed into the invention is a method for preparing a zinc oxide nano rod substrate. Detail descriptions of the steps and compositions will be provided in the following in order to make the invention thoroughly understood. Obviously, the application of the invention is not confined to specific details familiar to those who are skilled in the art. On the other hand, the common steps and compositions that are known to everyone are not described in details to avoid unnecessary limits of the invention. Some preferred embodiments of the present invention will now be described in greater detail in the following. However, it should be recognized that the present invention can be practiced in a wide range of other embodiments besides those explicitly described, that is, this invention can also be applied extensively to other embodiments, and the scope of the present invention is expressly not limited except as specified in the accompanying claims.

In one embodiment of the present invention, a method for preparing a zinc oxide nano rod substrate is disclosed. The zinc oxide nano rod substrate can be applied in pH tuning and modifying surface hydrophilicity.

At first, a blending process is performed to blend a zinc salt and an organic base reagent in an aqueous solution to form a mixture solution. The zinc salt is selected from the group consisting of the following: zinc nitrate, zinc acetate, zinc phosphate, and other salts containing zinc. In addition, the organic base reagent is an amino organic base selected from the group consisting of the following: methenamine and triethylenetetramine. In the mixture solution, the zinc salt and the organic base reagent has the same molar concentration where the molar concentration of the zinc salt and the organic base reagent is between 0.0025M and 0.1M.

Then, a substrate and a zinc oxide material are provided and a sputtering process is performed to have the zinc oxide material become nano particles and evenly deposited on the surface of the substrate to form an intermediate substrate. Finally, the intermediate substrate is immersed in the mixture solution and placed in a sealed container at a specific temperature between 85° C. and 95° C. so that a hydrothermal reaction is performed. Through the hydrothermal reaction, the zinc oxide nano particle as a nucleating center grows oriented to form a type of zinc oxide nano rods so as to form the zinc oxide nano rod substrate.

The above mentioned substrate is selected from the group consisting of the following: glass, zinc oxide, indium tin oxide (ITO), polyethylene terephthalate (PET), polymethyl methacrylate (PMMA), nylon, rayon, and the derivatives thereof.

In a preferred example of this embodiment, an annealing process is performed after the sputtering process where the reaction temperature of the annealing process is between room temperature and 150° C.

In another preferred example of this embodiment, after the above zinc oxide nano rod substrate is formed, the hydrothermal reaction on the formed zinc oxide nano rod substrate is performed repeatedly for continuing growing the zinc oxide nano rod so that the aspect ratio of the zinc oxide nano rod is increased.

### Example 1

### The Method for Preparing a Zinc Oxide Nano Rod Substrate

According to the method for preparing a zinc oxide nano rod substrate disclosed by the present invention, the detailed steps are as follows. At first, zinc nitrate and methenamine with the same molar concentration are blended together to form a mixture solution. Then, a layer of zinc oxide nano particles is sputtered on the surface of a substrate to be used as a crystal seed. The substrate can be selected from the group consisting of the following: glass, conductive glass, plastics, non-woven cloth. After that, the substrate is immersed in a sealed container containing the mixture solution. The sealed container is placed in an oven at 90° C. to have the hydrothermal reaction proceed for 6 hrs. After the reaction, the product is washed by water.

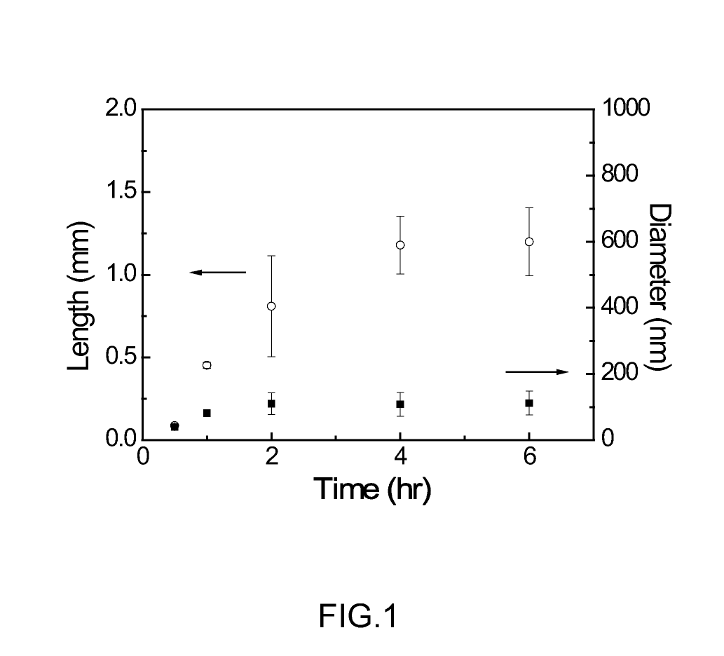

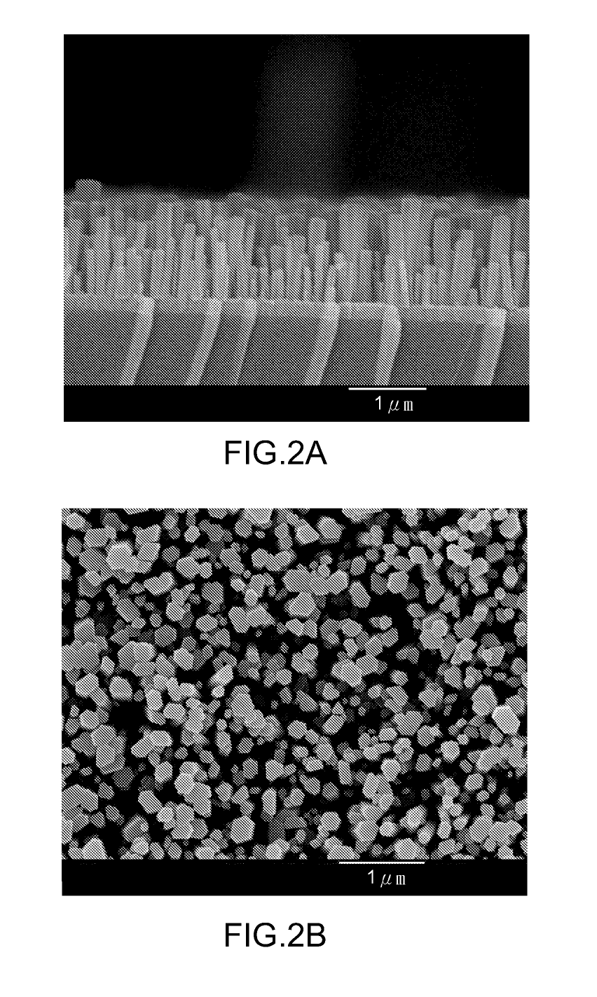

After the reaction, the zinc oxide nano rods are observed by a scanning electron microscope (SEM). It is found that the length and the cross sectional area of the zinc oxide nano rod become stable when the reaction time is from 4 hrs to 6 hrs, that is, the length and the cross sectional area are not increased any more, as shown in FIG. 1. Besides, The SEM images of the regularly arranged zinc oxide nano rods obtained by the above process in the oven at 90° C. for 6 hrs are shown in FIG. 2A and FIG. 2B.

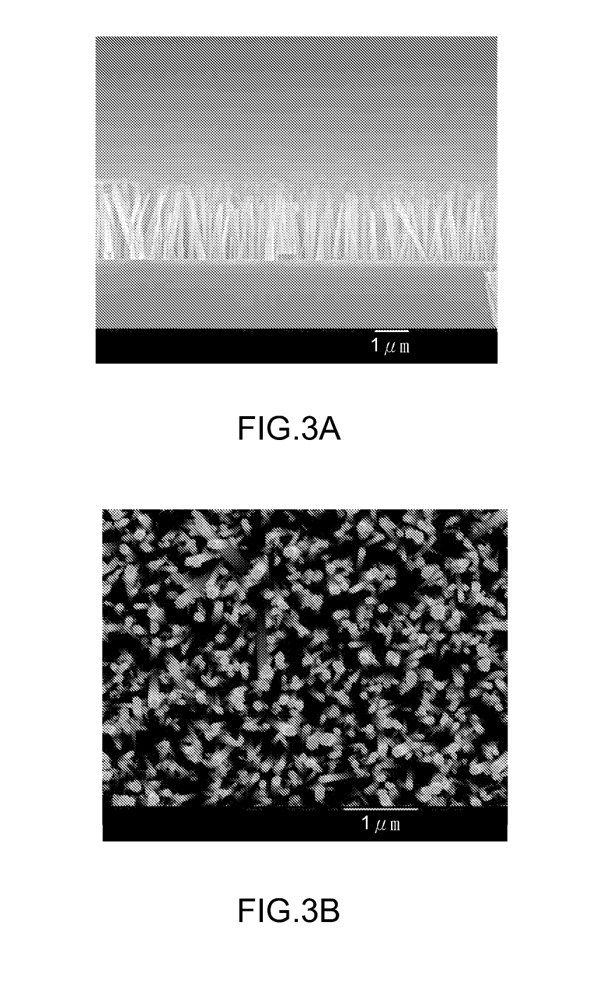

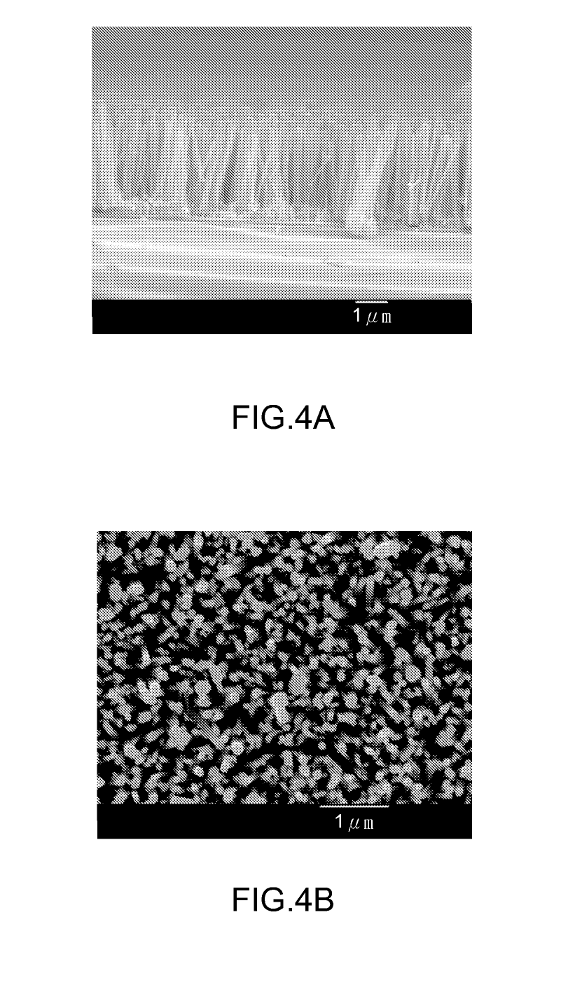

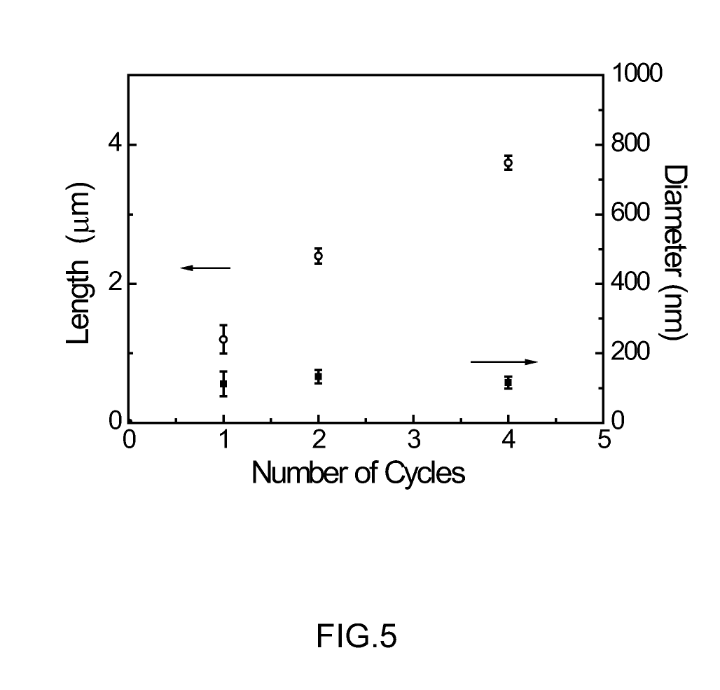

In order to further increase the height of the zinc oxide nano rod, the mixture solution can be replaced with a fresh mixture solution and the hydrothermal reaction is performed again for a total of 12-hour reaction time to further grow the regularly arranged zinc oxide nano rods, as shown in FIG. 3A and FIG. 3B. Besides, the SEM images of the zinc oxide nano rods undergoing a step of repeatedly replacing the mixture solution and performing the hydrothermal reaction four times for a total of 24-hour reaction time to further grow the regularly arranged zinc oxide nano rods are shown in FIG. 4A and FIG. 4B. The aspect ratio (AR) of the zinc oxide nano rod undergoing the hydrothermal reaction twice is 10 while the aspect ratio is 33 for undergoing the hydrothermal reaction four times. Thus, undergoing the hydrothermal reaction four times can increase the aspect ratio to 3.3 times and the surface area of zinc oxide is also increased, as shown in the following table and FIG. 5.

### The Number of Times Performing the Hydrothermal Reaction on the Zinc Oxide Nano Rod Substrate

| | 1 | 2 | 4 |
|---|---|---|---|
| Length (mm) | 1.2 | 2.3 | 3.8 |
| Diameter (nm) | 120 | 125 | 115 |
| Aspect ratio (AR) | 10 | 18 | 33 |

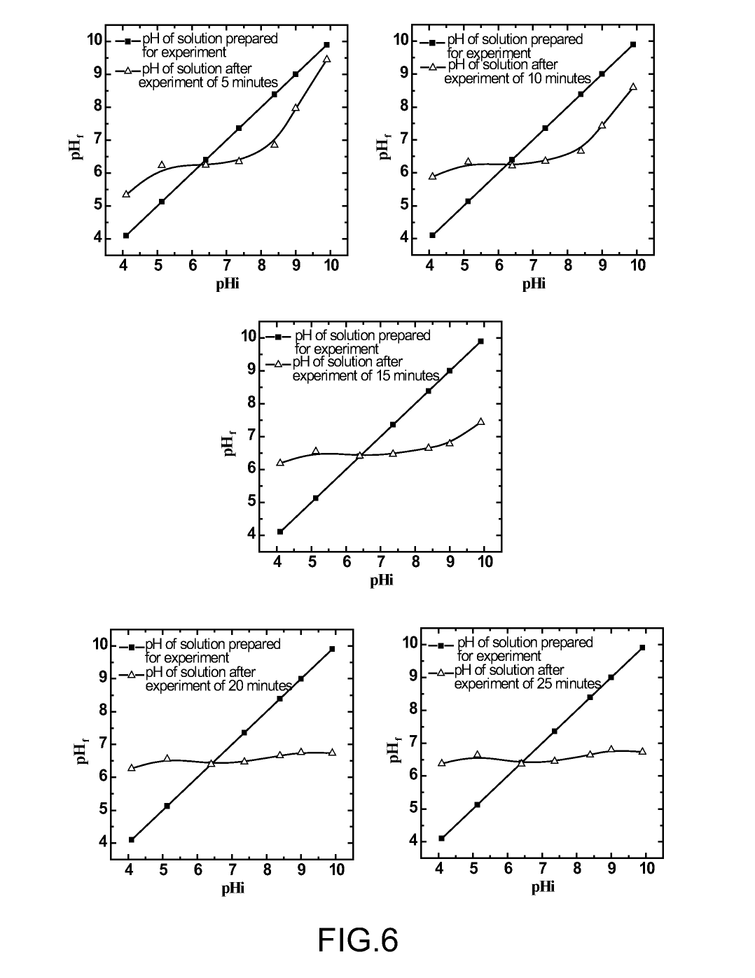

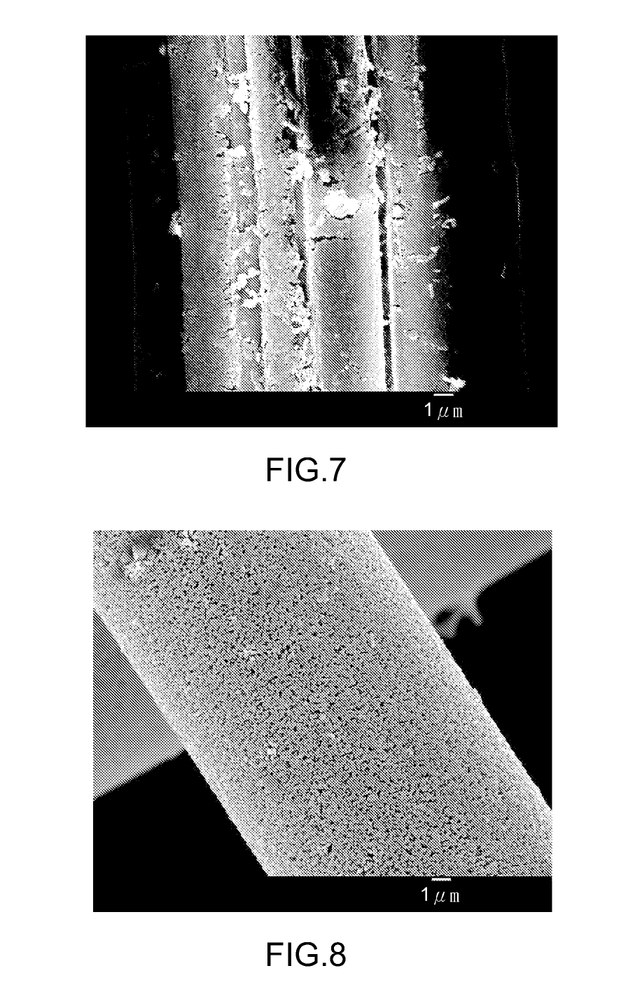

The above zinc oxide nano rod substrate undergoes the pH buffering test. It is found that under extreme acidic or basic conditions the reaction time for pH buffering is longer and within about 20 minutes to have the solution adjusted to become neutral, as shown in FIG. 6.

Furthermore, the substrate without undergoing the sputtering process is used to perform the hydrothermal reaction to have the zinc oxide nano rods deposited on the substrate but it is adsorption phenomenon. After water washing, the zinc oxide nano rods on the surface will be washed away and will not be regularly arranged on the substrate. Therefore, in the whole process, sputtering zinc oxide as a crystal seed is a very important step. Finally, this example uses non-woven cloth as the substrate, forms a layer of zinc oxide as a crystal seed by sputtering, and then grows zinc oxide nano rods by the hydrothermal reaction. The result is shown in FIG. 8. According to the above result, zinc oxide nano rods can be regularly arranged on the non-woven fiber so that the total surface area of zinc oxide is greatly increased. Moreover, the zinc oxide nano rods grown on non-woven fiber are precious in application.

Obviously many modifications and variations are possible in light of the above teachings. It is therefore to be understood that within the scope of the appended claims the present invention can be practiced otherwise than as specifically described herein. Although specific embodiments have been illustrated and described herein, it is obvious to those skilled in the art that many modifications of the present invention may be made without departing from what is intended to be limited solely by the appended claims.

What is claimed is:

1. A method for preparing a zinc oxide nano rod substrate, comprising:
performing a blending process to blend a zinc salt and an organic base reagent in an aqueous solution to form a mixture solution;
providing a substrate and a zinc oxide material and performing a sputtering process to have the zinc oxide material become nano particles and be evenly deposited on the surface of the substrate to form an intermediate substrate; and
immersing the intermediate substrate in the mixture solution and placed in a sealed container at a specific temperature so that a hydrothermal reaction is performed wherein, through the hydrothermal reaction, the zinc oxide nano particle as a nucleating center grows oriented to form a type of zinc oxide nano rods so as to form the zinc oxide nano rod substrate.

2. The method according to claim 1, wherein the zinc salt is selected from the group consisting of the following: zinc nitrate, zinc acetate, zinc phosphate, and other salts containing zinc.

3. The method according to claim 1, wherein the organic base reagent is an amino organic base.

4. The method according to claim 1, wherein the organic base reagent is selected from the group consisting of the following: methenamine and triethylenetetramine.

5. The method according to claim 1, wherein in the mixture solution the zinc salt and the organic base reagent has the same molar concentration.

6. The method according to claim 1, wherein in the mixture solution the molar concentration of the zinc salt and the organic base reagent is between 0.0025M and 0.1M.

7. The method according to claim 1, wherein the specific temperature is between 80° C. and 95° C.

8. The method according to claim 1, wherein the substrate is selected from the group consisting of the following: glass, zinc oxide, indium tin oxide (ITO), polyethylene terephthalate (PET), polymethyl methacrylate (PMMA), nylon, rayon, and the derivatives thereof.

9. The method according to claim 1, wherein an annealing process is performed after the sputtering process and the reaction temperature of the annealing process is between room temperature and 150° C.

10. The method according to claim 1, further comprising repeatedly performing a hydrothermal reaction on the zinc oxide nano rod substrate for continuing growing the zinc oxide nano rod to increase the aspect ratio of the zinc oxide nano rod after forming the zinc oxide nano rod substrate.

11. The method according to claim 1, wherein the zinc oxide nano rod substrate is applied in pH tuning and modifying surface hydrophilicity.
